(19) United States
(12) Patent Application Publication
(10) Pub. No.: US 2008/0055842 A1
(43) Pub. Date: Mar. 6, 2008

(54) Computer module with two transmission interfaces

(75) Inventors: Chih-Wei Chang, Hsi-Chih (TW); Cheng-Yun Lee, Hsi-Chih City (TW)

Correspondence Address: COOPER & DUNHAM, LLP, 1185 AVENUE OF THE AMERICAS, NEW YORK, NY, 10036, US

(73) Assignee: Suyin Corporation

(21) Appl. No.: 11/515,262

(22) Filed: Sep. 1, 2006

(51) Int. Cl. G06F 1/16; H05K 5/00; H05K 7/00

(52) U.S. Cl. 361/686

(57) ABSTRACT

A computer module with two transmission interfaces has a housing, a USB interface, an eSATA interface and a connecting seat. The housing has a cavity defined therein. The USB interface and the eSATA interface are mounted in the cavity side by side. The USB and eSATA interfaces mounted in the computer casing need only one opening, which reduces the cost of the computer casing. In addition, the computer module can also be applied to flat and thin notebooks or LCDs due to the “side by side” design.

### BACKGROUND OF THE INVENTION

1. Field of the Invention

The present invention relates to a transmission interface, and particularly relates to a two transmission interface module, which can be connected with the universal serial bus (USB) or external serial ATA (eSATA) plug.

2. Description of the Related Art

Computer periphery equipment such as flash drives, portable hard disc drives or external CD-ROM drives is connected with the computer through the USB interface or IEEE1394 protocol. The most popular interface is USB 2.0 at present, almost all the computer has the USB interface, and the upper limitation of the transmission speed of the USB 2.0 interface is as high as 480M bps.

With the development of the portable periphery equipment, the data transmission speed is higher and higher. The invention of the hard disc external box makes the hard disc drive portable, so the speed of USB 2.0 is not enough. A new interface, eSATA, which has an upper limitation of 3G bps and is enough for the portable hard disc drive, is developed.

However, USB 2.0 interface is still quite popular in the market, so it is natural for the computer has the eSATA interface as well as USB 2.0 interface. Conventional USB 2.0 and eSATA interfaces are in form of independent modules and are mounted through a computer casing. Therefore, the casing has multiple openings respectively corresponding to the independent modules. However, the mold opening of the casing with multiple openings has a high cost. Furthermore, an assembling problem that the independent modules can not entirely extend respectively through the openings in the casing probably happens when the casing has a low precision.

Therefore, the invention provides a computer module with two transmission interfaces to mitigate or obviate the aforementioned problems.

### SUMMARY OF THE INVENTION

The main objective of the present invention is to provide a computer module with two transmission interfaces that can be connected with the universal serial bus (USB) or external serial ATA (eSATA) plug.

The computer module in accordance with the present invention has a housing having a cavity defined therein; a USB interface mounted in the cavity; an eSATA interface mounted in the cavity, too.

The USB interface and the eSATA are horizontally arranged side by side.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of the computer module in accordance with the present invention;

FIG. 2 is another perspective view of the computer module in FIG. 1;

FIG. 3 is an exploded perspective view of the computer module in FIG. 1; and

FIG. 4 is another exploded perspective view of the computer module in FIG. 2.

### DETAILED DESCRIPTION OF THE PREFERRED EMBODIMENT

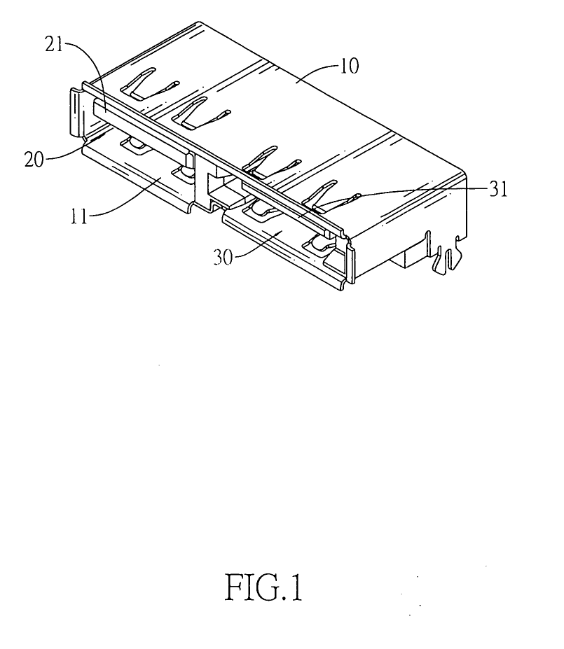

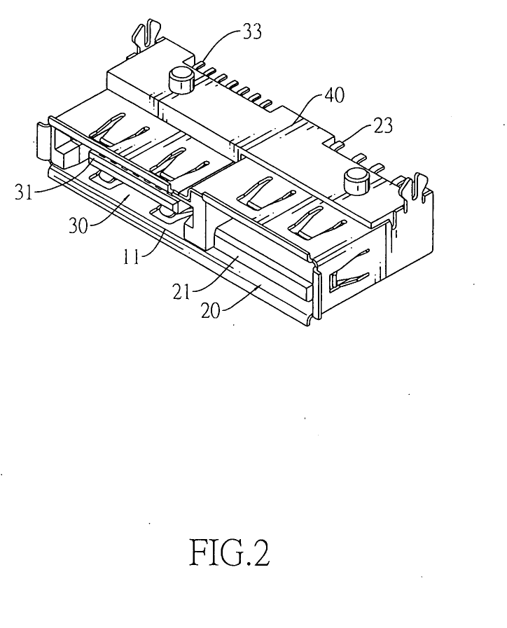

With reference to FIGS. 1-2, a computer module with two transmission interfaces has a housing (10), an universal serial bus (USB) interface (20), an external serial ATA (eSATA) interface (30) and a connecting seat (40).

A cavity (11) is defined in the housing (10).

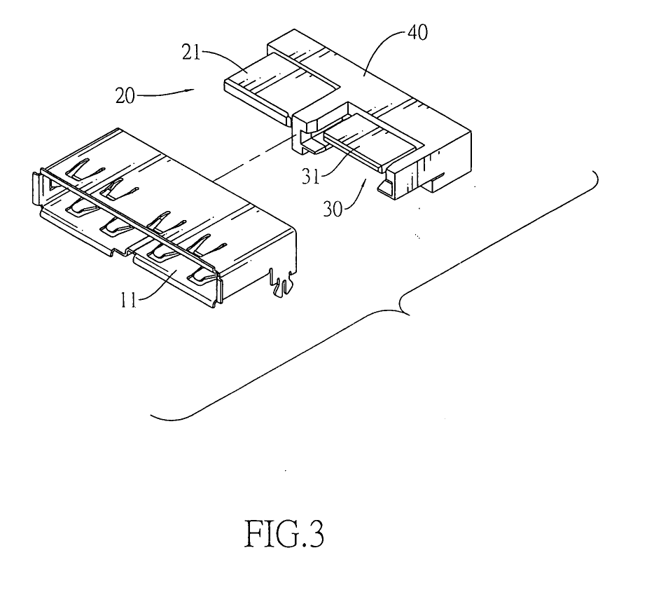

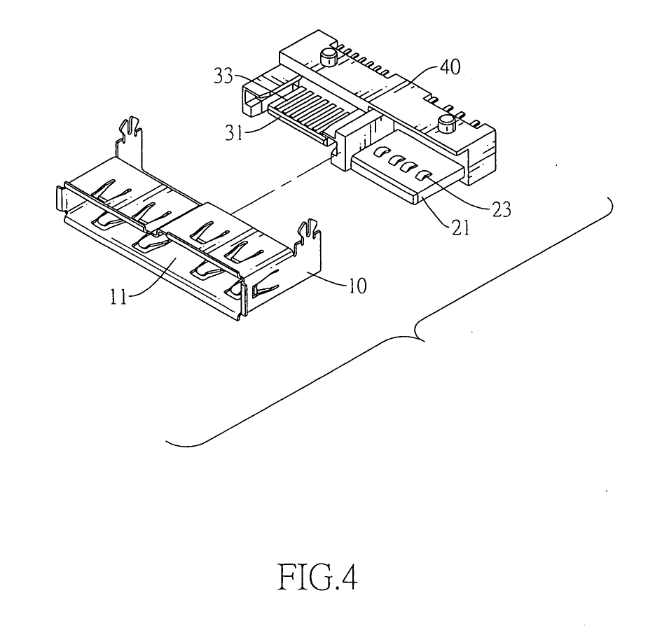

With reference to FIGS. 3-4, the USB interface (20) is mounted in one end of the cavity (11), and the USB interface (20) has a USB seat (21) and multiple USB metal contacts (23). The USB seat (21) is mounted in the cavity (11). The USB metal contacts (23) are mounted on the USB seat (21) in order to be electrically connected with a USB plug.

The eSATA interface (30) is mounted in the other end of the cavity (11), and the eSATA interface (30) has an eSATA seat (31) and multiple eSATA metal contacts (33). The eSATA seat (31) is mounted in the cavity (11). The eSATA metal contacts (33) is mounted on the eSATA seat (31) in order to be electrically connected with an eSATA plug.

The USB interface (20) and the eSATA interface (30) are horizontally arranged side by side.

The connecting seat (40) is mounted in the cavity (11) and is formed integrally with the USB seat (21) and the eSATA seat (31).

When the computer module with two transmission interfaces are mounted in the computer casing, only one opening defined through the casing is needed, thus opening the mold of the computer casing becomes easy and the cost of the computer casing is reduced. In addition, the “side by side” design makes the computer module thinner than similar product. Therefore, the computer module of the present invention can be further applied to a flat and thin electronic appliance such as liquid crystal displays (LCDs), or notebooks, etc.

It is to be understood, however, that even though numerous characteristics and advantages of the present invention have been set forth in the foregoing description, together with details of the structure and function of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A computer module with two transmission interfaces comprising:
a housing having a cavity defined therein;
an universal serial bus (USB) interface mounted in the cavity; and
an external serial ATA (eSATA) interface mounted in the cavity;
wherein the USB interface and the eSATA interface are horizontally arranged side by side.

2. The computer module with two transmission interface as claimed in claim 1, wherein the USB interface has a USB seat mounted in the cavity and multiple USB metal contacts mounted on the USB seat.

3. The computer module with two transmission interface as claimed in claim 2, wherein the eSATA interface has an eSATA seat mounted in the cavity and multiple eSATA metal contacts mounted on the eSATA seat.

4. The computer module with two transmission interface as claimed in claim 3, wherein a connecting seat is mounted in the cavity and is formed integrally with the USB seat and the eSATA seat.
